(19) United States
(12) Patent Application Publication
(10) Pub. No.: US 2021/0193396 A1
(43) Pub. Date: Jun. 24, 2021

(54) QUASI TWO-DIMENSIONAL LAYERED PEROVSKITE MATERIAL, RELATED DEVICES AND METHODS FOR MANUFACTURING THE SAME

(71) Applicant: THE GOVERNING COUNCIL OF THE UNIVERSITY OF TORONTO, Toronto, Ontario (CA)

(72) Inventors: Li Na QUAN, Toronto (CA); Francisco Pelayo GARCIA DE ARQUER, Toronto (CA); Randy Pat SABATINI, Rochester, NY (US); Sjoerd HOOGLAND, Toronto (CA); Edward SARGENT, Toronto (CA)

(21) Appl. No.: 16/757,233

(22) PCT Filed: Oct. 19, 2018
(86) PCT No.: PCT/CA2018/051319

§ 371 Date: Apr. 17, 2020

Related U.S. Application Data
(60) Provisional application No. 62/574,281, filed on Oct. 19, 2017.

(51) Int. Cl. H01G 9/20; H01G 9/00; H01L 51/00; H01L 51/42; H01L 51/44; H01L 51/50; H01L 51/52

(52) U.S. Cl. CPC H01G 9/2009; H01L 2251/308; H01G 9/2013; H01L 51/0003; H01L 51/0026; H01L 51/4253; H01L 51/442; H01L 51/448; H01L 51/5032; H01L 51/5056; H01L 51/5072; H01L 51/5088; H01L 51/5206; H01L 51/5221; H01L 51/5237; H01L 51/0077; H01L 51/0037; H01L 2251/301; H01G 9/0036

(57) ABSTRACT

Optoelectronic devices, such as photovoltaic device and light-emitting diode, are provided. The devices include a quasi two-dimensional layered perovskite material and a passivating agent chemically bonded to the quasi two-dimensional layered perovskite material. The passivating agent includes a phosphine oxide compound. An active material is also provided. The active material includes a quasi two-dimensional perovskite compound having outermost edge(s), and a passivating agent chemically bonded to the outermost edge(s). The passivating agent includes a phosphine oxide compound. Methods for manufacturing the optoelectronics devices and the active material are also provided.

### TECHNICAL FIELD

The technical field generally relates to two-dimensional material and related devices, as well as methods for manufacturing such material and devices. More particularly, the technical field relates to quasi two-dimensional layered perovskite material, related devices and methods for manufacturing the same, in the context of different optoelectronic applications.

### BACKGROUND

Two-dimensional metal-halide perovskite materials are an emerging class of materials with compelling advantages in optoelectronics compared to conventional three-dimensional perovskites (see for example references 1 to 4—PRIOR ART). The additional organic cations that confine two-dimensional perovskite layers result in a higher energy of formation, and this dramatically reduces degradation via moisture-induced decomposition (see for example references 2, 5 and 6—PRIOR ART). This has led to solar cells that exhibited remarkable stability improvements over their three-dimensional counterparts (see for example references 2, 3 and 6 to 8—PRIOR ART). The strong, tunable confinement of two-dimensional metal-halide perovskite materials allows the exciton binding energy to be increased well above the thermal dissociation threshold, leading to relatively good radiative rates needed in light-emission applications (see for example references 9 to 11—PRIOR ART).

The stability of two-dimensional perovskite materials (e.g., under light-emitting diode operating conditions or as an optically-pumped material) remains nevertheless a major roadblock to eventual deployment of this material in light-emission applications. Following sustained photoexcitation, these films rapidly deteriorate (e.g., in luminescence quantum yield).

The mechanisms behind the degradation remain the subject of debate. It was recently suggested that long-lived free-carriers accumulate at edge states of layered perovskites (see for example reference 13—PRIOR ART). This phenomenon, reported to be in some circumstances relatively beneficial for solar cell and light-emission applications, results in a high-excited state density close to layered perovskites' most vulnerable sites.

Challenges still exist in the field of two-dimensional perovskite materials and their implementation in different devices.

### SUMMARY

In accordance with one aspect, there is provided a photovoltaic device, including a first electrode and a second electrode in a spaced-apart configuration, an electron-transport layer coating at least a portion of the first electrode, a light-harvesting layer coating at least a portion of the electron-transport layer and being in electrical communication with the first electrode and the second electrode, the light-harvesting layer including a quasi two-dimensional layered perovskite material in electrical communication with the first electrode and the second electrode and a passivating agent chemically bonded to the quasi two-dimensional layered perovskite material, the passivating agent including a phosphine oxide compound, and a hole-transport layer coating at least a portion of the light-harvesting layer.

In some embodiments, the quasi two-dimensional layered perovskite material has at least one outermost edge including dangling bonds, and the phosphine oxide compound of the passivating agent is chemically bonded to the dangling bonds.

In some embodiments, the quasi two-dimensional layered perovskite material is made of a metal-halide perovskite.

In some embodiments, the metal-halide perovskite is selected from the PEA₂Cs₍ₙ₋₁₋ₓ₎MAₓPbₙBr₃ₙ₊₁ family, x being smaller than n−1.

In some embodiments, the metal-halide perovskite is selected from the PEA₂K₍ₙ₋₁₋ₓ₎MAₓPbₙBr₃ₙ₊₁ family, x being smaller than n−1.

In some embodiments, the metal-halide perovskite is selected from the PEA₂Cs₍ₙ₋₁₋ₓ₎FAₓPbₙBr₃ₙ₊₁ family, x being smaller than n−1.

In some embodiments, the quasi two-dimensional layered perovskite material includes domains, each domain including between one and five monolayers.

In some embodiments, each monolayer includes between two to four PbBr₆ unit cells.

In some embodiments, the phosphine oxide compound is soluble in polar perovskite solvents and in non-polar antisolvents.

In some embodiments, the phosphine oxide compound is triphenylphosphine oxide (TPPO).

In some embodiments, the first electrode is a conductive substrate.

In some embodiments, the conductive substrate is transparent.

In some embodiments, the conductive substrate includes glass coated with indium tin oxide (ITO).

In some embodiments, the second electrode includes a layered stack of lithium fluoride (LiF) and aluminum (Al).

In some embodiments, the hole-transport layer is made of PEDOT:PSS:PFI.

In some embodiments, the electron-transport layer is made of TPBi.

In accordance with one aspect, there is provided a solar cell, including a light-harvesting layer, including a quasi two-dimensional layered perovskite material and a passivating agent chemically bonded to the quasi two-dimensional layered perovskite material, the passivating agent including a phosphine oxide compound.

In some embodiments, the solar cell further includes a first electrode, an electron-transport layer coating at least a portion of the first electrode, a hole-transport layer coating at least a portion of the light-harvesting layer and a second electrode coating at least a portion of the hole-transport layer, the second electrode being in electrical communication with the first electrode.

In some embodiments, the solar cell further includes a first electrode, a hole-transport layer coating at least a portion of the first electrode, an electron-transport layer coating at least a portion of the light-harvesting layer and a second electrode coating at least a portion of the electron-transport layer, the second electrode being in electrical communication with the first electrode.

In some embodiments, the light-harvesting layer further includes a mesoporous metal oxide material.

In some embodiments, the solar cell further includes a first electrode, a compact layer coating at least a portion of the first electrode, a hole-transport layer coating at least a portion of the light-harvesting layer and a second electrode coating at least a portion of the hole-transport layer, the second electrode being in electrical communication with the first electrode.

In some embodiments, the solar cell further includes a first electrode, a compact layer coating at least a portion of the first electrode, an electron-transport layer coating at least a portion of the light-harvesting layer and a second electrode coating at least a portion of the electron-transport layer, the second electrode being in electrical communication with the first electrode.

In some embodiments, the solar cell further includes a lower-bandgap subcell.

In accordance with another aspect, there is provided an optoelectronic device, including a first electrode and a second electrode in a spaced-apart configuration, a quasi two-dimensional layered perovskite material in electrical communication with the first electrode and the second electrode and a passivating agent chemically bonded to the quasi two-dimensional layered perovskite material, the passivating agent including a phosphine oxide compound.

In some embodiments, the quasi two-dimensional layered perovskite material has at least one outermost edge including dangling bonds and the phosphine oxide compound of the passivating agent is chemically bonded to the dangling bonds.

In some embodiments, the quasi two-dimensional layered perovskite material is made of a metal-halide perovskite.

In some embodiments, the metal-halide perovskite is selected from the PEA₂Cs₍ₙ₋₁₋ₓ₎MAₓPbₙBr₃ₙ₊₁ family, x being smaller than n−1.

In some embodiments, the metal-halide perovskite is selected from the PEA₂K₍ₙ₋₁₋ₓ₎MAₓPbₙBr₃ₙ₊₁ family, x being smaller than n−1.

In some embodiments, the metal-halide perovskite is selected from the PEA₂Cs₍ₙ₋₁₋ₓ₎FAₓPbₙBr₃ₙ₊₁ family, x being smaller than n−1.

In some embodiments, the quasi two-dimensional layered perovskite material includes domains, each domain including between one and five monolayers.

In some embodiments, each monolayer includes between two to four PbBr₆ unit cells.

In some embodiments, the phosphine oxide is soluble in polar perovskite solvents and in non-polar antisolvents.

In some embodiments, the phosphine oxide is triphenylphosphine oxide (TPPO).

In some embodiments, the first electrode is a conductive substrate.

In some embodiments, the conductive substrate is transparent.

In some embodiments, the conductive substrate includes glass coated with indium tin oxide (ITO).

In some embodiments, the second electrode includes a layered stack of lithium fluoride (LiF) and aluminum (Al).

In some embodiments, the optoelectronic device further includes a hole-injection layer sandwiched between the first electrode and the quasi two-dimensional layered perovskite material.

In some embodiments, the hole-injection layer is coating at least a portion of the first electrode.

In some embodiments, the hole-injection layer is made of PEDOT:PSS:PFI.

In some embodiments, the optoelectronic device further includes an electron-transport layer sandwiched between the second electrode and the quasi two-dimensional layered perovskite material.

In some embodiments, the electron-transport layer is made of TPBi.

In some embodiments, the second electrode is coating at least a portion of the electron-transport layer.

In accordance with another aspect, there is provided, a light-emitting diode (LED), including a first electrode and a second electrode in a spaced-apart configuration, a hole-injection layer coating at least a portion of the first electrode, a light-emitting layer coating at least a portion of the hole-injection layer and being in electrical communication with the first electrode and the second electrode, the light-emitting material including a quasi two-dimensional layered perovskite material and a passivating agent chemically bonded to the quasi two-dimensional layered perovskite material, the passivating agent including a phosphine oxide compound, and an electron-transport layer coating at least a portion of the light-emitting layer.

In some embodiments, at least one the hole-injection layer, the light-emitting layer and the electron-transport layer is solution-processed.

In some embodiments, the hole-injection layer, the light-emitted material and the electron-transport layer are stacked between the first electrode and the second electrode.

In some embodiments, the LED is operable to generate an illuminating light having a spectral waveband ranging from about 490 nm to about 560 nm.

In some embodiments, the spectral waveband is centered at about 520 nm.

In some embodiments, the quasi two-dimensional layered perovskite material has at least one outermost edge including dangling bonds and the phosphine oxide compound of the passivating agent is chemically bonded to the dangling bonds.

In some embodiments, the quasi two-dimensional layered perovskite material is made of a metal-halide perovskite.

In some embodiments, the metal-halide perovskite is selected from the PEA₂Cs₍ₙ₋₁₋ₓ₎MAₓPbₙBr₃ₙ₊₁ family, x being smaller than n−1.

In some embodiments, the metal-halide perovskite is selected from the PEA₂K₍ₙ₋₁₋ₓ₎MAₓPbₙBr₃ₙ₊₁ family, x being smaller than n−1.

In some embodiments, the metal-halide perovskite is selected from the PEA₂Cs₍ₙ₋₁₋ₓ₎FAₓPbₙBr₃ₙ₊₁ family, x being smaller than n−1.

In some embodiments, the quasi two-dimensional layered perovskite material includes domains, each domain including between one and five monolayers.

In some embodiments, each monolayer includes between two to four PbBr₆ unit cells.

In some embodiments, the phosphine oxide is soluble in polar perovskite solvents and in non-polar antisolvents.

In some embodiments, the phosphine oxide is triphenylphosphine oxide (TPPO).

In some embodiments, the first electrode is a conductive substrate.

In some embodiments, the conductive substrate is transparent.

In some embodiments, the conductive substrate includes glass coated with indium tin oxide (ITO).

In some embodiments, the second electrode includes a layered stack of lithium fluoride (LiF) and aluminum (Al).

In some embodiments, the hole-transport layer is made of PEDOT:PSS:PFI.

In some embodiments, the electron-transport layer is made of TPBi.

In accordance with another aspect, there is provided an active material, the active material including a quasi two-dimensional perovskite compound, the quasi two-dimensional perovskite compound having at least one outermost edge and a passivating agent chemically bonded to the at least one outermost edge, the passivating agent including a phosphine oxide compound.

In some embodiments, the quasi two-dimensional perovskite compound includes domains, each domain including between one and five monolayers.

In some embodiments, the quasi two-dimensional perovskite compound includes a compound of general formula PEA₂Cs₍ₙ₋₁₋ₓ₎MAₓPbₙBr₃ₙ₊₁ family, x being smaller than n−1, wherein n is an integer greater than 0.

In some embodiments, a Cs-to-MA ratio ranges from 0% to 100%.

In some embodiments, the quasi two-dimensional perovskite compound is PEA₂Cs_{2.4}MA_{0.6}Pb₄Br₁₃.

In accordance with another aspect, there is provided a method for preparing a layer of active material, including: dissolving precursors in a first solvent to obtain a perovskite precursor solution; spin-coating the perovskite precursor solution on a surface to form a perovskite film on the surface; spin-coating a mixture including a phosphine oxide compound and a second solvent on the perovskite film to form an intermediate film; thermally treating the intermediate film, thereby obtaining the layer of active material, the active material including: a quasi two-dimensional layered perovskite compound; and a passivating agent chemically bonded to the quasi two-dimensional layered perovskite compound, the passivating agent including the phosphine oxide compound.

In some embodiments, the precursors include a PbBr₂ compound, a CsBr compound, a MABr compound and a PEABr compound.

In some embodiments, the PbBr₂ compound has a PbBr₂ molarity of about 0.6 M.

In some embodiments, the CsBr compound has a CsBr molarity of about 0.36M.

In some embodiments, the MABr compound has a MABr molarity of about 0.1 M.

In some embodiments, the PEABr compound has a PEABr molarity of about 0.3 M.

In some embodiments, the first solvent is dimethyl sulfoxide (DMSO).

In some embodiments, the phosphine oxide compound is triphenylphosphine oxide (TPPO).

In some embodiments, the second solvent is chloroform.

In some embodiments, thermally treating the intermediate film is carried out at about 90° C. for about seven minutes.

In accordance with another aspect, there is provided a method for manufacturing a photovoltaic device, including electrically contacting a light-harvesting layer with a first electrode, the light-harvesting layer including a quasi two-dimensional layered perovskite material in electrical communication with the first electrode and a passivating agent chemically bonded to the quasi two-dimensional layered perovskite material, the passivating agent including the phosphine oxide compound; electrically contacting the light-harvesting layer with a second electrode.

In some embodiments, the method further includes dissolving precursors in a first solvent to obtain a perovskite precursor solution; spin-coating the perovskite precursor solution on a surface to form a perovskite film on the surface; spin-coating a mixture including a phosphine oxide compound and a second solvent on the perovskite film to form an intermediate film; thermally treating the intermediate film, thereby obtaining the light-harvesting layer.

In some embodiments, the precursors include a PbBr₂ compound, a CsBr compound, a MABr compound and a PEABr compound.

In some embodiments, the PbBr₂ compound has a PbBr₂ molarity of about 0.6 M.

In some embodiments, the CsBr compound has a CsBr molarity of about 0.36 M.

In some embodiments, the MABr compound has a MABr molarity of about 0.1 M.

In some embodiments, the PEABr compound has a PEABr molarity of about 0.3 M.

In some embodiments, the first solvent is dimethyl sulfoxide (DMSO).

In some embodiments, the phosphine oxide compound is triphenylphosphine oxide (TPPO).

In some embodiments, the second solvent is chloroform.

In some embodiments, thermally treating the intermediate film is carried out at about 90° C. for about seven minutes.

In some embodiments, the method further includes providing an electron-transport layer between the first electrode and the light-harvesting layer.

In some embodiments, the method further includes providing a hole-transport layer between the light-harvesting layer and the second electrode.

In some embodiments, the method further includes providing a hole-transport layer between the first electrode and the light-harvesting layer.

In some embodiments, the method further includes providing an electron-transport layer between the light-harvesting layer and the second electrode.

In accordance with another aspect, there is provided a method for manufacturing an optoelectronic device, including coating a first electrode with a quasi two-dimensional layered perovskite material passivated with a passivating agent, the passivating agent being chemically bonded to the quasi two-dimensional layered perovskite material and including a phosphine oxide compound; and electrically contacting the quasi two-dimensional layered perovskite material passivated with the passivating agent with a second electrode.

In accordance with another aspect, there is provided a method for manufacturing a light-emitting diode (LED), including electrically contacting a light-emitting layer with a first electrode, the light-emitting layer including a quasi two-dimensional layered perovskite material in electrical communication with the first electrode; and a passivating agent chemically bonded to the quasi two-dimensional layered perovskite material, the passivating agent including the phosphine oxide compound; and electrically contacting the light-emitting layer with a second electrode.

In some embodiments, the method further includes preparing the light-emitting layer, including dissolving precursors in a first solvent to obtain a perovskite precursor solution; spin-coating the perovskite precursor solution on a surface to form a perovskite film on the surface; spin-coating a mixture including a phosphine oxide compound and a second solvent on the perovskite film to form an intermediate film; thermally treating the intermediate film, thereby obtaining the light-emitting layer.

In some embodiments, the precursors include a PbBr₂ compound, a CsBr compound, a MABr compound and a PEABr compound.

In some embodiments, the PbBr₂ compound has a PbBr₂ molarity of about 0.6 M.

In some embodiments, the CsBr compound has a CsBr molarity of about 0.36 M.

In some embodiments, the MABr compound has a MABr molarity of about 0.1 M.

In some embodiments, the PEABr compound has a PEABr molarity of about 0.3 M.

In some embodiments, the first solvent is dimethyl sulfoxide (DMSO).

In some embodiments, the phosphine oxide compound is triphenylphosphine oxide (TPPO).

In some embodiments, the second solvent is chloroform.

In some embodiments, thermally treating the intermediate film is carried out at about 90° C. for about seven minutes.

In some embodiments, the method further includes providing an electron-transport layer between the first electrode and the light-harvesting layer.

In some embodiments, the method further includes providing a hole-transport layer between the light-harvesting layer and the second electrode.

In some embodiments, the method further includes providing a hole-transport layer between the first electrode and the light-harvesting layer.

In some embodiments, the method further includes providing an electron-transport layer between the light-harvesting layer and the second electrode.

In some implementations, layered perovskite materials as described herein may exhibit relatively good mechanical, thermal, and optoelectronic stability. This stability stems from an edge-selective protection and a controlled crystallization of the perovskite materials. The controlled crystallization notably includes the incorporation of phosphine oxide molecules into the perovskite precursors during the perovskite material crystallization. In some embodiments, the phosphine oxide molecules modulate the kinetics of perovskite materials growth and passivate the perovskite material's unprotected edge sites. In some implementations, the combination of the perovskite materials and the phosphine oxides can be integrated into a device having the following properties: a photoluminescence quantum yield approximately equal to or even exceeding 95%. In some implementations, such a device can be under continuous illumination over 300 hours. In some implementations, the device can recover its optoelectronic performance after thermal and mechanical stress. In some embodiments, the combination of the perovskite material and the phosphine oxide can be implemented into a light-emitting diode emitting green light. In some embodiments, the light-emitting diode emits green light with an external quantum efficiency of about 14%. In some embodiments, the brightness of the emitted green light is substantially equal to about 100,000 cd/m². In some embodiments, devices integrating the combination of the perovskite materials and the phosphine have a projected stability of approximately 40 hours under continuous operation.

Other features will be better understood upon reading of embodiments thereof with reference to the appended drawings.

### BRIEF DESCRIPTION OF THE DRAWINGS

FIGS. 1A-C illustrate the exposed edge of a quasi two-dimensional layered perovskite material, as well a photoinduced degradation mechanism of the quasi two-dimensional layered perovskite material.

FIGS. 2A-F show a high-resolution transmission electron microscopy images of the quasi two-dimensional layered perovskite material, in accordance with one embodiment.

FIGS. 3A-B illustrate two optoelectronic device configurations. FIG. 3A shows a vertical configuration. FIG. 3B shows a horizontal configuration.

FIGS. 4A-E present implementations of a solar cell, in accordance with different embodiments.

FIG. 5A-E illustrate a light-emitting diode including a quasi two-dimensional layered perovskite layer, in accordance with one embodiment, as well as the light-emitting diode performances.

FIGS. 6A-E show the incorporation of a phosphine oxide in a quasi two-dimensional layered perovskite material, in accordance with one embodiment, as well as the photoluminescence properties of exfoliated quasi two-dimensional layered perovskite material.

FIGS. 7A-E illustrate the photophysical mechanisms, passivation and stability of quasi two-dimensional layered perovskite layer.

FIGS. 8A-B present the morphology of the unpassivated quasi two-dimensional layered perovskite and the morphology of passivated quasi two-dimensional layered perovskite.

FIGS. 9A-B show the results of X-ray diffraction measurements carried out on layers of different compositions.

FIG. 10 illustrates the absorption and photoluminescence spectra of unpassivated quasi two-dimensional layered perovskite and passivated quasi two-dimensional layered perovskite.

FIG. 11 illustrates a two-step spin-coating process for producing a perovskite layer.

### DETAILED DESCRIPTION

In the following description, similar features in the drawings have been given similar reference numerals. In order to not unduly encumber the figures, some elements may not be indicated on some figures if they were already mentioned in preceding figures. It should also be understood herein that the elements of the drawings are not necessarily drawn to scale and that the emphasis is instead being placed upon clearly illustrating the elements and structures of the present embodiments.

The description is generally directed towards a passivated layered perovskite material and related optoelectronic devices, including but not limited to photovoltaic devices (e.g., solar cells), light-emitting devices, light sensors, lasers and thermophotovoltaic devices, as well as methods for manufacturing the same.

The expression “active material” will be used throughout the description and refers to any material that is electrically active or responsive to an external electrical bias (“electroactive material”). The expression will also encompass material in which charge carriers are generated by light (i.e., photogenerated—“photoactive material”).

In the following description, the expressions “two-dimensional material”, “2D material”, “bidimensional material”, generally refer to material that can grow and/or extend along two axes, e.g., an x-axis and a y-axis, but not a z-axis. This is by contrast to “three-dimensional material”, “3D material”, “tridimensional material”, i.e. material that can grow and/or extend along three axes, e.g., an x-axis a y-axis, and a z-axis. Two-dimensional materials are generally crystalline materials including a single layer of atoms.

The expressions “quasi two-dimensional material”, “layered perovskites” or “Ruddlesden-Popper phase” are herein used to describe materials and/or crystals having a generally periodic structure in two dimensions (e.g., along an x-axis and a y-axis) and an atomic-size thickness that can include more than one layer of atoms in a third dimension (e.g., a z-axis).

In the context of the present description, the term “perovskite” will be used to refer to any material having the crystal structure ABX₃, wherein A and B are cations jointly bound to X, X being an anion. The expression “perovskite material” could encompass a broad variety of materials, for example and without being limitative, Cs_{0.87}MA_{0.13}PbBr₃, BABr:MAPbBr₃, MAPbBr₃, CsPbBr₃, MAPbBr₃, Cs₁₀MA_{0.17}FA_{0.83}Pb(BrₓI₁₋ₓ)₃, PEA₂MA₄Pb₅Br₁₆, FAPbBr₃, CsPbBr₃, CsPbBr₃, FA₍₁₋ₓ₎CsₓPbBr₃, MAPbBr₃, PEA₂Cs₃Pb₄Br₁₃, PEA₂Cs_{2.4}MA_{0.6}Pb₄Br₁₃, PEA₂Cs_{1.5}MA_{1.5}Pb₄Br₁₃, PEA₂Cs_{0.6}MA_{2.4}Pb₄Br₁₃ and PEA₂MA₃Pb₄Br₁₃

The expression “passivating agent” is herein understood as referring to atom(s), molecule(s), compound(s), layer(s), coating(s), or the like which can passivate a material's surface or edges. In the context of the current description, “passivate” refers to protecting a layer, a device or a portion thereof against deleterious effects through application of coating(s) or surface treatment (i.e., suppressing localized states that are detrimental for photo-, electrical, chemical and/or thermal properties, which are normally associated with and arise from dangling bonds and un/over coordinated surfaces). As such, the passivating agent can make inactive or can render less reactive a surface. The association of the material's surface with the molecule(s), compound(s), layer(s), coating(s), or the like will be referred to as a “passivated surface”. Generally, passivation involves that the passivated surface is less affected by its environment than the original (i.e., not passivated) material's surface.

The passivating agent can be chemically bonded to the material's surface. In the following the expression “chemically bonded” could refer to different type of chemical bonds, for examples and without being limitative: covalent bond, electrostatic bond, ligand/metal bond, ionic bond, metallic bond, dipole-dipole interaction, hydrogen bonding, coordinate covalent bond or any other relevant chemical bonds.

### General Theoretical Overview

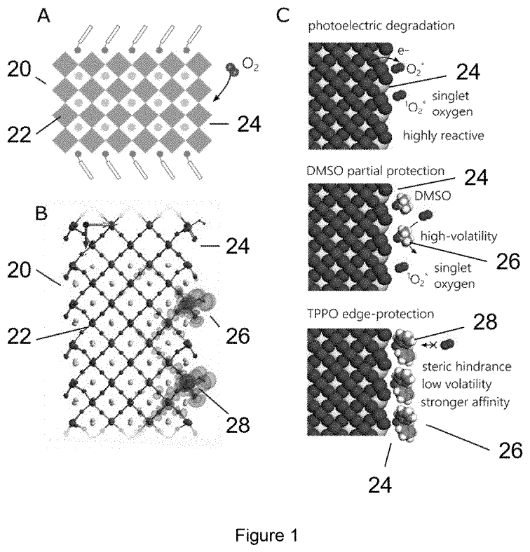

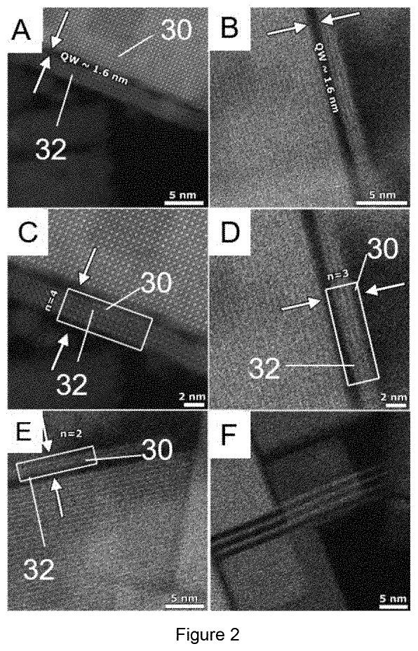

With reference to FIGS. 1 and 2, typical challenges associated with the integration of quasi two-dimensional perovskite material into optoelectronic devices, as well as the reported degradation mechanisms of such material will now be described in greater detail.

Generally, it has been postulated that it is near or at the exciton-accepting edges of the quasi two-dimensional perovskite material that the highest density of dangling bonds and under-coordinated atoms are present. The exciton-accepting edges, sometimes referred to “outermost edges” or simply “edges” hence act as vulnerable sites for the quasi two-dimensional perovskite material and, as such, moisture and oxygen adsorption are susceptible to deteriorate the quasi two-dimensional layered perovskite material near or at these edges. Furthermore, in some scenarios, for example and without being limitative under photoexcitation, the edges could also be the recipients of significant transferred energy and charge carriers. For instance, once photoexcited, the charge carriers transferred near the edges could readily be injected into oxygen molecules absorbed at the edges, hence turning them into reactive oxygen singlets (¹O₂), thereby triggering the perovskite material decomposition.

This situation is more clearly depicted in FIGS. 1A-C. In FIG. 1A, an edge of the quasi two-dimension layered perovskite is illustrated as being rich in Pb dangling bond sites. Those sites are exposed to the adsorption of nucleophilic molecules, which could include but are not limited to oxygen, any other atoms, groups of atoms and/or molecules. In FIG. 1B, the adsorption of molecular oxygen results in localized states and traps. One skilled in the art would readily understand that such localized states and traps are susceptible to deteriorate the optoelectronic properties of the quasi two-dimensional perovskite material. In FIG. 1C, the transfer of photoexcited charge carriers (illustrated, in the depicted embodiment, as being electrons) into adsorbed oxygen results in the generation of oxygen singlets. Such singlets are known to be highly reactive, and can trigger, in some circumstances, the deterioration of the perovskite material. In some embodiments, such deterioration is irreversible. Some materials could be used to protect the edges of the quasi two-dimensional perovskite material. An example of such materials is dimethyl sulfoxide (DMSO), which could provide the quasi two-dimensional perovskite material with partial protection. However, DMSO does not withstand the annealing temperature required to crystallize the quasi two-dimensional perovskite material.

The abovementioned deterioration mechanism of the quasi two-dimensional perovskite material has been corroborated with density functional theory (DFT) calculations. DFT calculations provide a charge-balanced edge reconstruction (see for example references 14 and 15) of the quasi two-dimensional layered perovskite material and reveals that one dangling bond was exposed per Pb atom (see reference 16). More particularly, this dangling bond does not on its own form a trap state, but remains exposed, thereby allowing the adsorption of a variety of nucleophilic molecules (e.g., molecular oxygen) that readily form a dative bond (i.e., a coordinate covalent) with the exposed edge of the quasi two-dimensional perovskite material, as illustrated in FIG. 1A. Oxygen adsorption can result in the generation of electronic traps in the quasi two-dimensional perovskite material bandgap in a similar manner to other semiconductors (see for example reference 17). In some scenarios, a photodegradation pathway can be triggered when a photoexcited electron is transferred from the quasi two-dimensional perovskite material to O₂, thereby resulting in a reactive singlet oxygen radical (¹O₂) that could irreversibly split the molecule and convert it into a chemisorbed oxide species (see for example reference 18).

A benign Lewis base adduct that outcompetes oxygen adsorption could be used to passivate the quasi two-dimensional perovskite material to overcome the abovementioned challenges. Such a Lewis base could improve the quasi two-dimensional perovskite material stability in an oxygen-rich ambient. Examples of Lewis base include polar aprotic solvents that are used to dissolve perovskite precursors, such as and without being limitative, dimethylsulfoxide (DMSO), dimethylformamide (DMF) and N-Methyl-2-pyrrolidone (NMP). While such Lewis bases do form adducts with metal halides and could be used to retard the formation of perovskite crystals and control the film morphology (see for example references 19 to 21), the Lewis base-metal complexes being formed with volatile solvents typically cannot withstand the annealing step that is required for film formation or crystallization of the film. Therefore, the metal dangling bond of the annealed films can remain vulnerable to oxygen attack (see for example reference 22).

The following description will present embodiments of a passivation technique (sometimes referred to as a “surface treatment”) which enable the use of compound having similar electronic properties, as well as stabilization and passivation effects of the abovementioned Lewis bases, but that are sufficiently robust to withstand the annealing step. In some implementations, the surface treatment could also be resistant to further thermal stress and/or other sources of stress (e.g., mechanical stress), for instance during operation of an optoelectronic device integrating such a material.

DFT calculations energies for the O:Pb bond show that phosphine-oxide compound has a higher binding energy to Pb (approximately equal to 1.1 eV), compared to S═O (approximately equal to 0.8 eV) and O═O (approximately equal to 0.3 eV). As such, the edge of the quasi two-dimensional perovskite material can be passivated using a phosphine oxide compound.

Based on this general overview and related theoretical predictions, different phosphine oxides of varying organic residue lengths as Lewis base molecules were used to passivate the quasi two-dimensional perovskite material. The Lewis base molecules are typically capable to form bonds with the edge of the quasi two-dimensional perovskite material. In some embodiments, the Lewis base molecules are TPPO molecules which could be incorporated into the perovskite film during the spin-coating process, as it will be described in the sections describing the methods of manufacturing such passivated quasi two-dimensional perovskite material.

### Active Material

Embodiments of an active material 20 will now be described with references to FIGS. 1 and 2. The active material 20 includes a quasi two-dimensional perovskite compound 22.

The quasi two-dimensional perovskite compound 22 includes a compound of general formula PEA₂Cs₍ₙ₋₁₋ₓ₎MAₓPbₙBr₃ₙ₊₁ family, x being smaller than n−1, wherein n is an integer greater than 0. The Cs-to-MA ratio ranges from 0% to 100%.

In one embodiment, the quasi two-dimensional perovskite compound is PEA₂Cs_{2.4}MA_{0.6}Pb₄Br₁₃.

The quasi two-dimensional perovskite compound 22 can be, for example and without being limitative, PEA₂Cs₃Pb₄Br₁₃, PEA₂Cs_{1.5}MA_{1.5}Pb₄Br₁₃, PEA₂Cs_{0.6}MA_{2.4}Pb₄Br₁₃ or PEA₂MA₃Pb₄Br₁₃. The quasi two-dimensional perovskite compound 22 has at least one outermost edge 24.

In alternate embodiments, the quasi two-dimensional perovskite compound 22 can include other metal than Cs, such as, and without being limitative, potassium (K). The amine ligands could be FA or other ammonium groups.

The active material 20 also includes a passivating agent 26 chemically bonded to the outermost edge(s) 24 of the quasi two-dimensional perovskite compound 22. As such, the passivating agent 26 is not incorporated alongside the precursor or dispersed in the quasi two-dimensional perovskite compound 22, but rather coats the outermost edge(s) 24 of the quasi two-dimensional perovskite compound 22. The quasi two-dimensional perovskite compound 22 is thereby passivated and could sometimes be referred to as the “passivated perovskite compound”.

The passivating agent 26 includes a phosphine oxide compound 28. The phosphine oxide compound 28 is soluble in the perovskite solvents (polar) and in the antisolvents (non-polar). Nonlimitative examples of solvents are DMSO, DMF and/or NMF. Nonlimitative examples of antisolvents are toluene and chloroform.

In some embodiments, the phosphine oxide 28 compound is triphenylphosphine oxide (TPPO).

The quasi two-dimensional perovskite compound 22 includes domains 30, each domain 30 including between one and five monolayers 32. More precisely, FIG. 2 presents high-angle annular dark field (HAADF) scanning transmission electron microscopy (STEM) images of layered perovskites illustrating the presence of domains with different number of layers.

As illustrated, individual sheets consist of one to four PbBr₆ unit cells can be clearly resolved. FIG. 2 also shows that the distance between the domains 30 (or, alternatively between the monolayers 32 of each domain 30, which are sometimes referred to as “stacked sheets”) is approximately 1.5 to 1.6 nm, which substantially corresponds to the phenethylamine (PEA) organic interlayer thickness.

### Optoelectronic Device

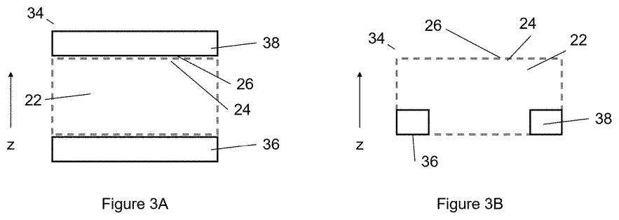

Now turning to FIGS. 3A-B, examples of an optoelectronic device 34 architectures are illustrated and will now be described.

In the depicted embodiments, the optoelectronic device 34 includes a first electrode 36 and a second electrode 38 in a spaced-apart configuration. The spaced-apart configuration could either be in a vertical configuration (FIG. 3A) or in a horizontal configuration (FIG. 3B). The configuration is determined as a function of the direction of the driving force of the charge transport. In the context of the following description, the vertical configuration is herein understood as the configuration enabling the charge transport to take place in a substantially vertical direction (i.e., a direction extending in a direction substantially parallel to the force of gravity), whereas the horizontal configuration is herein understood as the configuration enabling the charge transport to take place in a substantially horizontal direction (i.e., a direction extending in a direction substantially perpendicular to the force of gravity).

The optoelectronic device 34 could also have a multiterminal configuration, for example and without being limitative, as LED-transistor configuration. In this example, the optoelectronic device would require a bottom gate electrode.

The optoelectronic device 34 includes a quasi two-dimensional layered perovskite material 22. The quasi two-dimensional layered perovskite material 22 is in electrical communication with the first electrode 36 and the second electrode 38. The expression “electrical communication” means that the quasi two-dimensional layered perovskite material 22 could either be in direct or indirect contact with the first electrode 36 and/or the second electrode 38, i.e., without the presence or with intermediate layers, respectively, as long as charge carriers (e.g., electrons and holes) can be extracted (in the context of photovoltaic or sensing applications) or injected (in the context of light emission) at a corresponding one of the first electrode 36 and second electrode 38. The quasi two-dimensional layered perovskite material 22 has at least one outermost edge 24 (sometimes simply referred to as “edge(s)”, “external edge(s)”, “exposed edge(s)”, or the like).

The optoelectronic device 34 also includes a passivating agent 36. The passivating agent 36 is chemically bonded to the quasi two-dimensional layered perovskite material 22 and includes a phosphine oxide compound 28. As it has been previously described, the edges 24 of the quasi two-dimensional perovskite material 22 include dangling bonds, and the phosphine oxide compound 28 of the passivating agent 26 is chemically bonded to the dangling bonds. In some embodiments, the passivating agent 26 is chemically bonded to the dangling bonds through covalent bonds.

The optoelectronic device 34 includes, in some embodiments, a metal-halide perovskite. As such, the quasi two-dimensional layered perovskite material 22 can include a compound of general formula PEA₂Cs₍ₙ₋₁₋ₓ₎MAₓPbₙBr₃ₙ₊₁ family, x being smaller than n−1, wherein n is an integer greater than 0. The Cs-to-MA ratio ranges from 0% to 100%.

In one embodiment, the quasi two-dimensional perovskite compound is PEA₂Cs_{2.4}MA_{0.6}Pb₄Br₁₃.

The quasi two-dimensional layered perovskite material 22 can be, for example and without being limitative, PEA₂Cs₃Pb₄Br₁₃, PEA₂Cs_{2.4}MA_{0.6}Pb₄Br₁₃, PEA₂Cs_{1.5}MA_{1.5}Pb₄Br₁₃, PEA₂Cs_{0.6}MA_{2.4}Pb₄Br₁₃ or PEA₂MA₃Pb₄Br₁₃. The quasi two-dimensional perovskite layered material 22 is passivated by the passivating agent 26 and could sometimes be referred to as the “passivated layered perovskite material”. In some embodiments, the thickness of the layer comprising the passivated layered perovskite material could range from about 50 nm to about 100 nm. In one embodiment, the thickness of the passivated layered perovskite material is about 90 nm.

As for the composition of the passivating agent 26, the passivating agent 26 includes a phosphine oxide compound 28. The phosphine oxide compound 28 is soluble in polar perovskite solvents and in non-polar antisolvents.

In some embodiments, the phosphine oxide 28 compound is triphenylphosphine oxide (TPPO).

In alternate embodiments, the quasi two-dimensional layered perovskite material 22 can include a compound of general formula PEA₂CsₓMA₃₋ₓPb₄Br₁₃, wherein x ranges from about 0 to about 3.

In some embodiments, the quasi two-dimensional layered perovskite material 22 can comprise domains 30, each domain comprising between one and five monolayers 32. The crystallographic orientation of each domain 30 could be different from one another. In some embodiments, each monolayer 32 comprises between two to four PbBr₆ unit cells.

Now turning back to the architecture of the optoelectronic device 34, the first electrode 36 can be a conductive substrate. In some embodiments, the conductive substrate is transparent. The conductive transparent substrate could comprise, for example and without being limitative glass coated with indium tin oxide (ITO). Alternatively, any other conductive transparent substrate known from one skilled in the art could be used.

The second electrode 38 can comprise a layered stack of lithium fluoride (LiF) and aluminum (Al). In some embodiments, the second electrode 38 comprises a 1-nm thick LiF layer coated with a 100-nm thick Al layer. Alternatively, the thickness of the LiF layer and/or the Al layer could vary. These layers are typically deposited using thermal evaporation technique, but other deposition techniques could also be used.

In some embodiments, the optoelectronic device 34 includes a hole-injection layer sandwiched (not illustrated in FIGS. 3A-B) between the first electrode 36 and the quasi two-dimensional layered perovskite material 22. The hole-injection layer can coat at least a portion of the first electrode.

The hole-injection layer can comprise at least one organic compound or a combination thereof. For example, and without being limitative, the hole-injection layer can be made of PEDOT:PSS:PFI. In some embodiments, the thickness of the hole-injection layer could range from about 150 nm to about 200 nm. In one embodiment, the thickness of the hole-injection layer is about 170 nm.

In some embodiments, the optoelectronic device 34 includes an electron-transport layer (not shown in FIGS. 3A-B) sandwiched between the second electrode 38 and the quasi two-dimensional layered perovskite material 22. The electron-transport layer can coat at least a portion of the quasi two-dimensional layered perovskite material.

The electron-transport layer can comprise a comprise at least one organic compound or a combination thereof. For example, and without being limitative, the electron-transport layer can be made of 2,2′,2″-(1,3,5-Benzinetriyl)-tris(1-phenyl-1-H-benzimidazole) (simply referred to as “TPBi”). In some embodiments, the thickness of the electron-transport layer could range from about 20 nm to about 50 nm. In one embodiment, the thickness of the electron-transport layer is about 40 nm.

In some embodiments, the second electrode 38 is coating at least a portion of the electron-transport layer.

In the depicted embodiment of FIG. 3A, the optoelectronic device 34 includes a plurality of successive layers, each extending along a substantially horizontal direction (i.e., along a direction substantially perpendicular to the force of gravity), starting from the bottom: the first electrode 36, the hole-injection layer (not illustrated), the quasi two-dimensional layered perovskite material 22, the electron-transport layer (not illustrated in FIGS. 3A-B) and the second electrode 38. Alternatively, the architecture of the optoelectronic device of FIG. 3A could also be “inverted”. In such an inverted architecture, the plurality of successive layers is (bottom-up): the first electrode 36, the electron-transport layer (not illustrated in FIGS. 3A-B), the quasi two-dimensional layered perovskite material 22, the hole-injection layer and the second electrode 38. A horizontal configuration, such as the one depicted in FIG. 3B could also be used.

### Photovoltaic Implementations

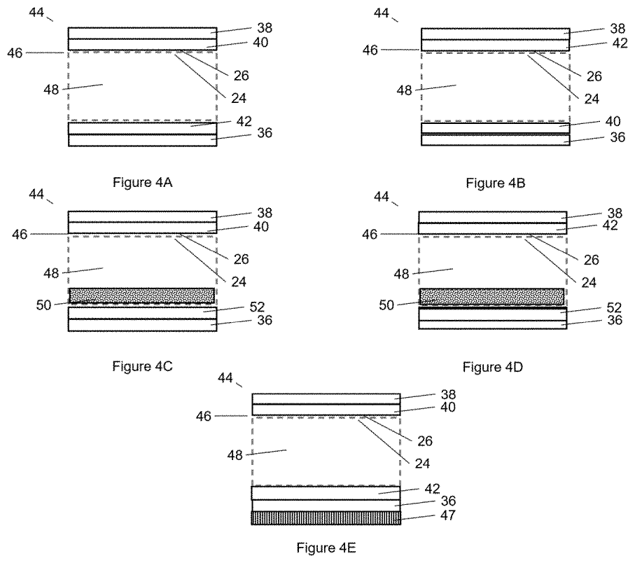

The quasi two-dimensional layered perovskite material 22 passivated with the passivating agent 26 can be implemented into a photovoltaic device 44, such as the one illustrated in FIGS. 4A-E. In the context of the current description, the expression “photovoltaic device” refers to devices that allow the conversion of light into electricity. An example of a photovoltaic device 44 is a solar cell 46. A photovoltaic device 44 can include one or more solar cell(s) 46. A solar cell 46 includes a light-harvesting material or layer 48 (sometimes referred to as an “absorber”). The solar cell 46 is typically designed and configured to generate charge carriers, such as electron-hole pairs or excitons, upon absorption of light, separate the charge carriers of opposite types and extract the charge carrier to an external circuit to be powered. The solar cell 46 generally includes collecting electrodes (e.g., the first electrode 36 and the second electrode 38), as well as a hole-transport layer 40 and an electron-transport layer 42. In the context of photovoltaic applications, one function of the hole-transport layer 40 and the electron-transport layer 42 is to avoid leak current by blocking the flow of electrons (in the case of the hole-transport layer) towards one of the electrodes 36 or 38 and blocking the flow of holes (in the case of the electron-transport layer) towards the other one of the electrodes 36 or 38. Another function of the hole-transport layer 40 and the electron-transport layer 42 is charge transport. Indeed, the hole-transport layer 40 and the electron-transport layer 42 typically have a better charge transporting properties compared with the light-harvesting layer 48. As such, the generated charges reaching the interfaces with the corresponding interface of the hole-transport layer 40 and the electron-transport layer 42 can be drifted away from the light-harvesting layer 48 towards the respective electrode 36, 38, which limits or in some cases avoids charge recombination before their collection by the respective electrode 36, 38. While a broad variety of materials could be used for forming the hole-transport layer 40 and electron-transport layer 42, one skilled in the art would readily understand that the energetic levels of the hole-transport layer 40 and electron-transport layer 42 match the energy levels of the light-harvesting layer 48.

In some embodiments, additional layers could be provided between the electron-transport layer, the light-harvesting layer and/the hole-transport layer. Examples of such additional layers include but are not limited to phenethylammonium iodide (PEAI) and/or poly(methyl methacrylate) (PMMA).

The light-harvesting layer 48 includes a quasi two-dimensional layered perovskite material 22 and a passivating agent 26 chemically bonded to the quasi two-dimensional layered perovskite material 22. The quasi two-dimensional layered perovskite material 22 and the passivating agent 26 are similar to the ones which have been previously described

Now turning to FIGS. 4A-E, different configurations of the solar cell 46 are illustrated.

In FIGS. 4A-B, a regular n-i-p configuration and an inverted p-i-n configuration are shown. In the former configuration (regular n-i-p configuration), the electron-transport layer 42 is coating at least a portion of the first electrode 36 and the hole-transport layer 40 coating at least a portion of the light-harvesting layer 48. The second electrode 38 is coating at least a portion of the hole-transport layer 40. In the latter configuration (inverted p-i-n configuration), the hole-transport layer 40 is coating at least a portion of the first electrode 36 and the electron-transport layer 42 is coating at least a portion of the light-harvesting layer 48. The second electrode 38 is coating at least a portion of the electron-transport layer 42.

In FIGS. 4C-D, two mesoscopic configurations are illustrated, the first one being a regular mesoscopic n-i-p configuration and the second being an inverted mesoscopic p-i-n configuration. In the mesoscopic configurations, the light-harvesting layer 48 further comprises a mesoporous metal oxide material 50. The metal oxide material 50 could be, for example and without being limitative, TiO₂

In the former configuration (regular mesoscopic n-i-p configuration), the solar cell 46 includes a first electrode 36, a compact layer 52 coating at least a portion of the first electrode 36, a hole-transport layer 40 coating at least a portion of the light-harvesting layer 48 and a second electrode 38 coating at least a portion of the hole-transport layer 40. The second electrode 38 is in electrical communication with the first electrode. In this configuration, the mesoporous metal oxide material 50 is embedded in the light-harvesting layer 48 and acts as an electron-transport layer 42.

In the latter configuration (inverted mesoscopic p-i-n configuration), the solar cell 46 includes a first electrode 36, a compact layer 52 coating at least a portion of the first electrode 36, an electron-transport layer 42 coating at least a portion of the light-harvesting layer 48 and a second electrode 38 coating at least a portion of the electron-transport layer 42. The second electrode 38 is in electrical communication with the first electrode 36. In this configuration, the mesoporous metal oxide material 50 is embedded in the light-harvesting layer 48 and acts as a hole-transport layer 40.

With reference to FIG. 4E, a tandem configuration is illustrated. The tandem configuration can include any one of solar cells 46 which have been described or a combination thereof. The tandem configuration also includes a lower-bandgap subcell 47. The lower-bandgap subcell 47 is connected in series with the other solar cell(s) 46. The tandem configuration could be, for example and without being limitative, double- or triple-junction cells.

### Light-Emitting Diode Implementations

The quasi two-dimensional layered perovskite material 22 passivated with the passivating agent 26 can be implemented into a light-emitting diode 54 or similar light-emitting devices. In the context of the current description, the expression “light-emitting diode” refers to devices emitting light when activated, i.e., when an electrical current circulates therein.

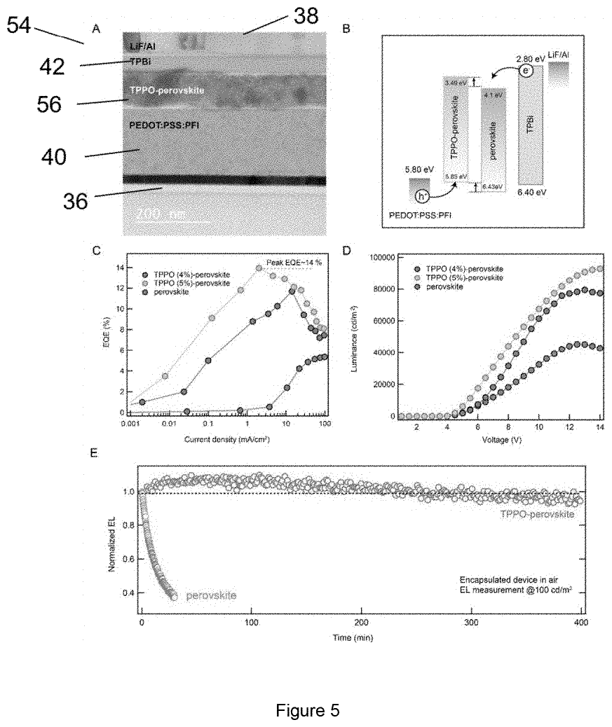

Different configurations and architectures of the light-emitting diode 54 can be achieved. One is illustrated in FIGS. 5A-E. It is to be noted that the light-emitting diode 54 can include the layer(s) described in the context of the optoelectronic device 34 and the photovoltaic device 54. As such, the number of layers, as well as their composition can be similar to what has been previously described. Generally described, the light-emitting diode 54 includes a first electrode 36 and a second electrode 38 in a spaced-apart configuration, a hole-injection layer 40, a light-emitting layer 56 and an electron-transport layer 42. The hole-injection layer 40 is coating at least a portion of the first electrode 36. The light-emitting layer 56 is coating at least a portion of the hole-injection layer 40 and is in electrical communication with the first electrode 36 and the second electrode 38. The light-emitting layer 56 includes a quasi two-dimensional layered perovskite material 22 and a passivating agent 26 chemically bonded to the quasi two-dimensional layered perovskite material 22. The passivating agent 26 includes a phosphine oxide compound 28. The electron-transport layer 42 is coating at least a portion of the light-emitting layer 56.

Although similar layers (e.g., hole-transport layer 40 and electron-transport layer 42) and/or materials are used in photovoltaic devices 44 and in light-emitting diodes 54, their functions can be slightly different. For example, in the light-emitting diode implementations, the hole-transport layer 40 and the electron-transport layer 42 are such that the recombination close to the interface with the corresponding electrodes is limited or at least reduced, which could be used to limit emission efficiencies quenching. The presence of hole-transport layer 40 and electron-transport layer 42 hence allow to “pushes away” the charges from the electrodes 36, 38 (towards a center portion of the light-emitting material), which can result in larger recombination area near or at the center of the light-emitting layer 56. While a broad variety of materials could be used for forming the hole-transport layer 40 and electron-transport layer 42, one skilled in the art would readily understand that the energetic levels of the hole-transport layer 40 and electron-transport layer 42 match the energy levels of the light-emitting material.

In some embodiments, the light-emitting diode 54 is operable to generate an illuminating light having a spectral waveband ranging from about 490 nm to about 560 nm.

In some embodiments, the spectral waveband is centered at about 520 nm.

It would be readily understood that the passivated layered perovskite material could be integrated into many other optoelectronic devices, such as and without being limitative light source (e.g., laser), light sensors, thermophotovoltaic device, thermal transport device, and the like.

### Methods

Now that different embodiments of the materials and related devices have been described, different methods for preparing and manufacturing the same will now be presented.

### Method for Preparing a Layer of Active Material

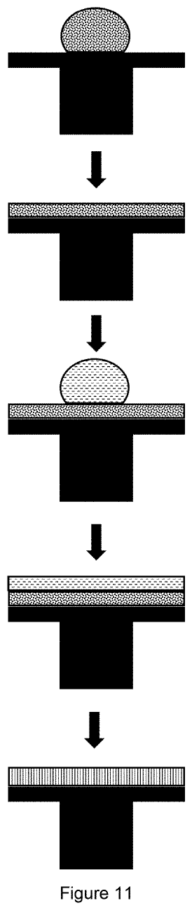

A method for preparing a layer of active material will now be described. Some steps of this method are illustrated in FIG. 11.

The method includes the steps of dissolving precursors in a first solvent to obtain a perovskite precursor solution; spin-coating the perovskite precursor solution on a surface to form a perovskite film on the surface; spin-coating a mixture comprising a phosphine oxide compound and a second solvent on the perovskite film to form an intermediate film; thermally treating the intermediate film, thereby obtaining the layer of active material. The active material includes a quasi two-dimensional layered perovskite compound and a passivating agent chemically bonded to the quasi two-dimensional layered perovskite compound, the passivating agent comprising the phosphine oxide compound. In alternate embodiments, at least one of the spin-coating steps could be replaced by of the following deposition techniques: blade coating (sometimes referred to as “knife coating” or “doctor blading”), spray casting (sometimes referred to as “spray forming”), ink-jet printing, or similar deposition technique.

In some embodiments, the precursors include a PbBr₂ compound, a CsBr compound, a MABr compound and a PEABr compound.

In some embodiments, PbBr₂ compound has a PbBr₂ molarity of about 0.6 M.

In some embodiments, the CsBr compound has a CsBr molarity of about 0.36 M.

In some embodiments, the MABr compound has a MABr molarity of about 0.1 M.

In some embodiments, the PEABr compound has a PEABr molarity of about 0.3 M.

In some embodiments, the first solvent is dimethyl sulfoxide (DMSO).

In some embodiments, the phosphine oxide compound is triphenylphosphine oxide (TPPO).

In some embodiments, the second solvent is chloroform.

In some embodiments, thermally treating the intermediate film is carried out at about 90° C. for about seven minutes.

### Method for Manufacturing an Optoelectronic Device

Different optoelectronic devices including the active material prepared according to the method presented above can be manufactured.

There is provided a method for manufacturing an optoelectronic device. The method includes steps of coating a first electrode with a quasi two-dimensional layered perovskite material passivated with a passivating agent, the passivating agent being chemically bonded to the quasi two-dimensional layered perovskite material and comprising a phosphine oxide compound; and electrically contacting the quasi two-dimensional layered perovskite material passivated with the passivating agent with a second electrode.

### Method for Manufacturing a Photovoltaic Device

There is also provided a method for manufacturing a photovoltaic device. The method for manufacturing the photovoltaic device includes electrically contacting a light-harvesting layer with a first electrode, wherein the light-harvesting layer includes a quasi two-dimensional layered perovskite material in electrical communication with the first electrode and a passivating agent chemically bonded to the quasi two-dimensional layered perovskite material, the passivating agent comprising the phosphine oxide compound. The method for manufacturing the photovoltaic device also includes electrically contacting the light-harvesting layer with a second electrode.

In some embodiments, the method for manufacturing the photovoltaic device can comprise substeps for preparing the light-harvesting layer. Such substeps include dissolving precursors in a first solvent to obtain a perovskite pre-cursor solution; spin-coating the perovskite precursor solution on a surface to form a perovskite film on the surface; spin-coating a mixture comprising a phosphine oxide compound and a second solvent on the perovskite film to form an intermediate film; thermally treating the intermediate film, thereby obtaining the light-harvesting layer.

In some embodiments, the precursors comprise a PbBr₂ compound, a CsBr compound, a MABr compound and a PEABr compound. In one implementation, the PbBr₂ compound has a PbBr₂ molarity of about 0.6 M, the CsBr compound has a CsBr molarity of about 0.36 M, the MABr compound has a MABr molarity of about 0.1M and PEABr compound has a PEABr molarity of about 0.3 M. In this implementation, the first solvent is dimethyl sulfoxide (DMSO), the phosphine oxide compound is triphenylphosphine oxide (TPPO) and the second solvent is chloroform. The thermal treatment could also be carried out at about 90° C. for about seven minutes, but other thermal treatment process could also be used.

In some embodiments, the method for manufacturing the photovoltaic devices also includes providing an electron-transport layer between the first electrode and the light-harvesting layer. The electron-transport layer can be spin-coated or deposited with other deposition techniques on the first electrode prior to the deposition (via spin-coating) of the light-harvesting layer. Similarly, the method for manufacturing the photovoltaic devices can also includes a step of providing a hole-transport layer between the light-harvesting layer and the second electrode. The hole-transport layer can be spin-coated or deposited with other deposition technique (e.g., thermal evaporation) on the light-harvesting layer prior to the deposition of the second electrode.

In alternate embodiments, the method for manufacturing the photovoltaic devices also includes providing a hole-transport layer between the first electrode and the light-harvesting layer. The hole-transport layer can be spin-coated or deposited with other deposition techniques on the first electrode prior to the deposition (via spin-coating) of the light-harvesting layer.

Similarly, the method for manufacturing the photovoltaic devices can also include a step of providing an electron-transport layer between the light-harvesting layer and the second electrode. The electron-transport layer can be spin-coated or deposited with other deposition technique on the light-harvesting layer prior to the deposition of the second electrode.

### Method for Manufacturing a Light-Emitting Diode

There is also provided a method for manufacturing a light-emitting diode. The method includes steps of electrically contacting a light-emitting layer with a first electrode, wherein the light-emitting layer includes a quasi two-dimensional layered perovskite material in electrical communication with the first electrode and a passivating agent chemically bonded to the quasi two-dimensional layered perovskite material, the passivating agent comprising the phosphine oxide compound, and electrically contacting the light-emitting layer with a second electrode.

In some embodiments, the method for manufacturing the light-emitting diode can comprise substeps of preparing the light-emitting layer. Such substeps include dissolving precursors in a first solvent to obtain a perovskite precursor solution; spin-coating the perovskite precursor solution on a surface to form a perovskite film on the surface; spin-coating a mixture comprising a phosphine oxide compound and a second solvent on the perovskite film to form an intermediate film; thermally treating the intermediate film, thereby obtaining the light-emitting layer.

In some embodiments, the precursors comprise a PbBr₂ compound, a CsBr compound, a MABr compound and a PEABr compound. In one implementation, the PbBr₂ compound has a PbBr₂ molarity of about 0.6 M, the CsBr compound has a CsBr molarity of about 0.36 M, the MABr compound has a MABr molarity of about 0.1M and PEABr compound has a PEABr molarity of about 0.3 M. In this implementation, the first solvent is dimethyl sulfoxide (DMSO), the phosphine oxide compound is triphenylphosphine oxide (TPPO) and the second solvent is chloroform. The thermal treatment could also be carried out at about 90° C. for about seven minutes, but other thermal treatment process could also be used.

In some embodiments, the method for manufacturing the light-emitting diode also includes providing an electron-transport layer between the first electrode and the light-harvesting layer. The electron-transport layer can be spin-coated or deposited with other deposition techniques on the first electrode prior to the deposition (via spin-coating) of the light-harvesting layer. Similarly, the method for manufacturing the photovoltaic devices can also includes a step of providing a hole-transport layer between the light-harvesting layer and the second electrode. The hole-transport layer can be spin-coated or deposited with other deposition technique (e.g., thermal evaporation) on the light-harvesting layer prior to the deposition of the second electrode.

### Example of Implementation of a Method for Manufacturing a Light-Emitting Diode

In one embodiment, a mixed solution of PEDOT:PSS (Clevios™ PVP Al4083) and perfluorinated ionomer, tetrafluoroethylene-perfluoro-3,6-dioxa-4-methyl-7-octenesulfonic acid copolymer (PFI) (PEDOT:PSS:PFI=1:6:25.4 (w:w:w)) was spin-coated on oxygen-plasma-treated, patterned ITO-coated glass substrates, then annealed on a hot plate at 150° C. for 20 minutes in air. Perovskite precursor solutions were spin-coated onto the PEDOT:PSS via a two-step spin-coating method similar to the one that was described above. TPBi (60 nm) and LiF/Al electrodes (1 nm/100 nm) were deposited using a thermal evaporation system under a high vacuum of less than 10⁻⁴ Pa. The light-emitting diode active area was 6.14 mm² as defined by the overlapping area of the ITO and Al electrodes. The light-emitting diodes were encapsulated before the measurements. All devices were tested under ambient condition.

### Experimental Results

Now referring to FIGS. 5 to 10, experimental results will now be presented to illustrate the working principle and different features of the optoelectronic devices which have been described in previous sections.

Quasi two-dimensional layered perovskite materials (referred in this section as the “layered perovskite films”) were investigated. In one implementation, the layered perovskite films have the general formula PEA₂Cs₂₄MA_{0.6}Pb₄Br₁₃ and are prepared by the relatively fast crystallization spin-coating method presented above.

The layered perovskite films show a bright green emission at λ=517 nm (i.e., near 520 nm) and exhibits high photoluminescence quantum yield (PLQY), by comparison with other material from the AₙA′ₙ₋₁PbₙBr₃ₙ₊₁ family. In a previous study, PEA₂(MAI)ₙ₋₁PbₙI₃ₙ₊₁ films with lower n values (n≥2) were shown to be a multi-phase material. This enables ultra-fast energy transfer from high-bandgap to small-bandgap n grains, confirmed by transient absorption measurements, and leads to efficient radiative recombination.

The following table illustrates the effect of the mixing ratio of Cs-MA on the PLQY in the context of quasi two-dimensional layered perovskite material. It is shown that the highest PLQY is reach with the PEA₂Cs_{2.4}MA_{0.6}Pb₄Br₁₃ composition.

TABLE 1
PLQY of different mixing ratio of Cs-MA

| Perovskites | PLQY (%) |
|---|---|
| PEA₂Cs₃Pb₄Br₁₃ | 40 |
| PEA₂Cs_{2.4}MA_{0.6}Pb₄Br₁₃ (MA20%) | 75 |
| PEA₂Cs_{1.5}MA_{1.5}Pb₄Br₁₃ (MA50%) | 50 |
| PEA₂Cs_{0.6}MA_{2.4}Pb₄Br₁₃ (MA80%) | 45 |
| PEA₂MA₃Pb₄Br₁₃ (MA100%) | 60 |

The following table illustrates the detail parameters of a device including the layered perovskite film as the light-emitting layer. More particularly, the device is a green-emitting diode having an external quantum efficiency of about 14% and brightness of about 100000 cd/m². Different measurements were carried out to characterize the light-emitting diode. The results are presented in FIG. 5.

TABLE 2
Detail parameters of device performances

| | | | | | η_{EQE} (%) | | η_{PE} (Im W⁻¹) | | J_{sc} (mA cm⁻²) | |
|---|---|---|---|---|---|---|---|---|---|---|
| | V_{T} | λₘₐₓ | FWHM | Lₘₐₓ | | @ 1000 | | @ 1000 | | @ 1000 |
| | (V) | (nm) | (nm) | (cdm⁻²) | peak | cd m⁻² | peak | cd m⁻² | peak | cd m⁻² |
| Perovskite | 3 | 523 | 27 | 26700 | 4.5 | 3.39 | 7.87 | 6.8 | 327 | 4.3 |
| Edge-protected- | 2.5 | 520 | 27 | 45200 | 13.95 | 13.8 | 31.69 | 30 | 364 | 2.2 |
| perovskite | | | | | | | | | | |

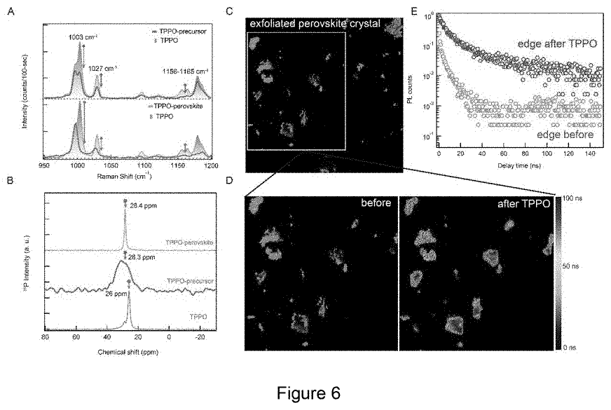

To verify that TPPO binds the perovskite edge and is not merely incorporated alongside the precursor, Raman spectroscopy was used. The TPPO Raman spectrum agrees with the established literature frequency values, serving as an important control for comparison upon addition of PbBr₂ (see FIG. 6). Solid state ³¹P nuclear magnetic resonance (NMR) spectroscopy was used to investigate the interaction of TPPO with the layered perovskite film. Chemical shifts in TPPO-precursor and TPPO-perovskite compared with bare TPPO was reported, which is an indication that of the changing coordination of phosphorus.

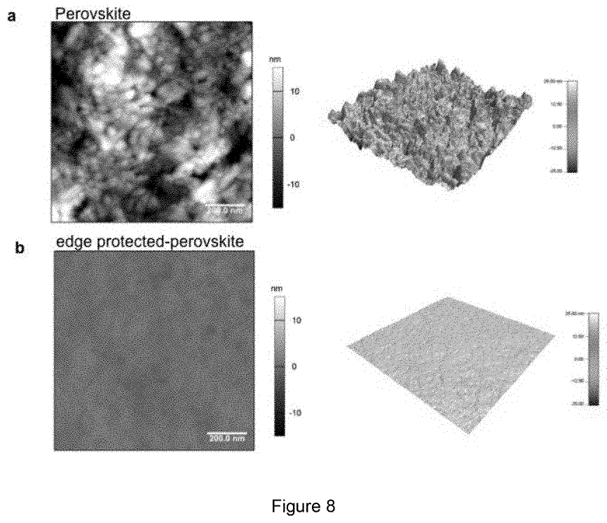

The morphology of the film was investigated with atomic force microscopy (AFM). As illustrated in FIG. 8, the surface's condition of the layered perovskite film is changed (e.g., the RMS roughness) following the passivation by the phosphine compound.

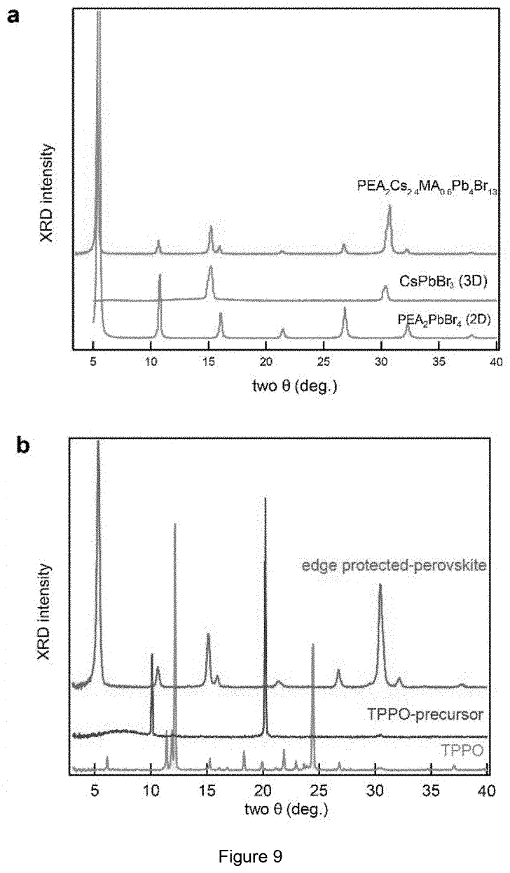

X-ray diffraction (XRD) measurements were used to confirm that the perovskite crystal structure was maintained, even if the edges of the layered perovskite films were passivated by the phosphine oxide compound, as illustrated in FIG. 9.

To shed light on the protecting nature of TPPO (i.e., of the phosphine oxide compound on the quasi two-dimensional layered perovskite material), single crystals of layered perovskite material were produced. Confocal fluorescence microscopy was used to spatially resolve the photoluminescence decay dynamics from the edges and centers of the mechanically exfoliated perovskite flakes. Photoluminescence decay mapping show longer decay times at the edges than in the center of the thin crystals consisting of a multiple stacked both vertically and laterally small 2D domains, as shown in FIG. 6. The PL decay time of the edges increases by 4 times after addition of TPPO, whereas the PL decay at the center does not change noticeably. These results provide a direct evidence of edge passivation by TPPO.

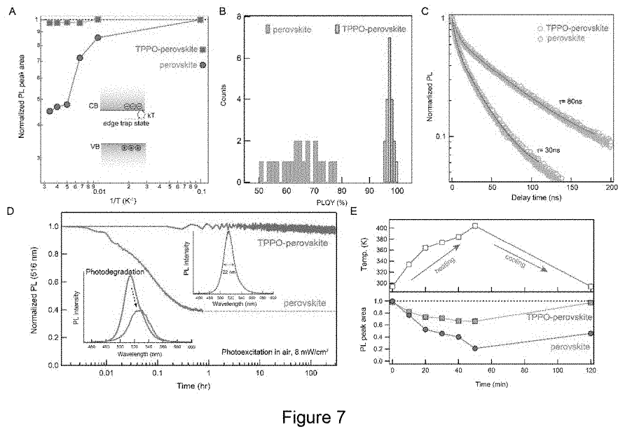

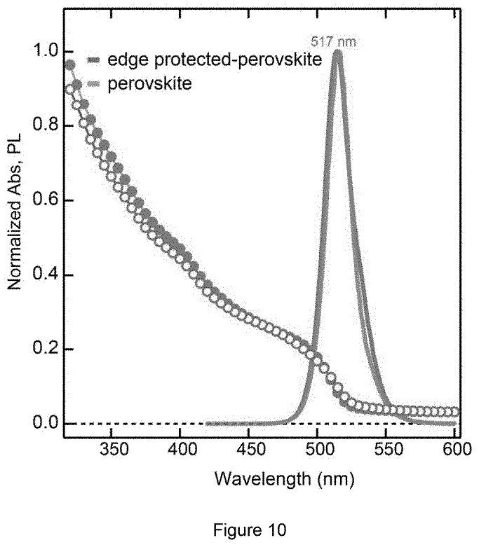

Now turning to FIG. 7, the optical properties of quasi two-dimensional layered perovskite layer and TPPO-passivated quasi two-dimensional layered perovskite layer were measured. The PL spectrum of the quasi two-dimensional layered perovskite layer and TPPO-passivated quasi two-dimensional layered perovskite layer reveal emission wavelengths located around 517 nm, the TPPO-passivated quasi two-dimensional layered perovskite layer showing a narrower emission (full-width at half-maximum of 22 nm, see for example FIG. 10).

Temperature-dependent photoluminescence measurements were also carried out to investigate the role of TPPO on the passivation of edge traps (see FIG. 7A). As the temperature decreases and trap-assisted recombination becomes sluggish, the PL intensity of perovskite steadily increases. The PL intensity of TPPO-passivated quasi two-dimensional layered perovskite layer remains unchanged, suggesting negligible trapping even at room temperature. This result agrees with the measured near-unity PLQY values of TPPO-passivated quasi two-dimensional layered perovskite layer (97±2%) compared to control perovskite samples (60±10%) (see FIG. 7B) and the extended radiative decay time of TPPO samples (see FIG. 7C).

Because of its edge protection, the TPPO-passivated quasi two-dimensional layered perovskite layer shows much greater photo-stability than pure perovskites (FIG. 7D). The photoluminescence of different samples under continuous excitation with 8 mW/cm² 400 nm light in air with ±40% relative humidity was monitored. The emission of pure perovskite samples degrades down to a 40% of its initial value within an hour, with a notorious broadening and a redshift. The TPPO-passivated quasi two-dimensional layered perovskite layer, on the other hand, retains its original brightness during the course of 300 hours of unencapsulated continuous illumination in air. The emission peak remains substantially unchanged. The optoelectronic properties of the TPPO-passivated quasi two-dimensional layered perovskite layer also exhibit excellent reversibility during thermal testing, consistently recovering the near unity PLQY after heating cycles up to 424 K (FIG. 7E). In the case of unpassivated perovskite films, most of the PL is lost during the heating process, and about 50% of initial PL is recovered after cooling down to room temperature. This is in contrast to TPPO-passivated quasi two-dimensional layered perovskite layer, which loses about around 25% of its initial PL, but recovers entirely when cooling down back to room temperature.

The TPPO-passivated quasi two-dimensional layered perovskite layer was integrated in a LED device architecture sequentially including the following layers: ITO, PEDOT:PSS:PFI, TPPO-passivated quasi two-dimensional layered perovskite layer, TPBi and LiF/Al. The PEDOT:PSS:PFI layer is known to have excellent exciton-buffering and hole-injection capabilities. TPBi acts as an electron transport layer and LiF/AI as an electrode (e.g., a cathode electrode).

Ultraviolet photoemission spectroscopy (UPS) measurements were used to determine the valence band positions and work functions of the perovskites and TPPO-perovskites, as illustrated in FIG. 5B. The swallower work function of TPPO-passivated quasi two-dimensional layered perovskite layer compared to unpassivated perovskite improves band alignment with the anode.

A maximum EQE of 14% and a luminance of 93,000 cd/m² were achieved for LED including a TPPO-passivated quasi two-dimensional layered perovskite layer. Control unpassivated perovskite-based LEDs showed a moderate efficiency, with 5.4% EQE and 45,230 cd/m² luminance. The high device performance of TPPO-passivated quasi two-dimensional layered perovskite layer was achieved even at low current densities, where trap-mediated recombination are known to be more problematic, indicating a substantially low trap density in the light emitting layer consistent with the near-unity PLQY of the material.

One of the critical issues in perovskite-based LEDs of the prior art is the extremely low operational stability under constant current. Best operational device stability of perovskite LEDs is as short as hundred seconds under a certain applied bias. The degradation mechanism induced by the combination of light and oxygen is suggested to be the primary degradation pathway under the device operation. Even in encapsulated devices, oxygen molecules would remain inside the perovskite material, contributing to photo-electrical degradation of the devices.

In the context of LED including a TPPO-passivated quasi two-dimensional layered perovskite layer as described in the current disclosure, the encapsulated LED retained 95% of its initial 100 cd/m² luminance after 400 minutes of operation, whereas control perovskite LEDs lost most of their performance within 30 minutes, as illustrated in FIG. 5. All the measurements have been carried out in air with encapsulation.

It has also been suggested that the interfacial contact between perovskite/TPBi and LiF/AI is a critical issue for limiting the operational stability. During the stability test, moisture can diffuse from the Al layer into the device, limiting the device stability (29). Thus, the accelerated device lifetime of T₅₀ high luminance and low luminance. The device stability of TPPO-passivated quasi two-dimensional layered perovskite layer shows a lifetime of 44.6 hours under accelerated conditions.

The passivation of the edges of the layered perovskite materials with a phosphine oxide compound exhibits edges results in their perfect passivation (PLQY˜97%). The passivation also allows to limit or even suppress the photodegradation mechanisms triggered by the activation of highly reactive oxygen singlets. The phosphine oxide compound is typically added to the perovskite during perovskite film formation and passivates the exposed edges. These phosphine oxide-perovskite materials exhibit a relatively good robustness against oxygen, moisture and heat. When implemented in LEDs, a 13.95% EQE and a luminance of 93,000 cd/m² is achieved. The projected operational lifetime of T₅₀ is about 44.6 hours under continuous operation. These results pave the way to the deployment of high-efficiency and stable perovskite-based LEDs.

Several alternative embodiments and examples have been described and illustrated herein. The embodiments described above are intended to be exemplary only. A person skilled in the art would appreciate the features of the individual embodiments, and the possible combinations and variations of the components. A person skilled in the art would further appreciate that any of the embodiments could be provided in any combination with the other embodiments disclosed herein. The present examples and embodiments, therefore, are to be considered in all respects as illustrative and not restrictive. Accordingly, while specific embodiments have been illustrated and described, numerous modifications come to mind without significantly departing from the scope defined in the appended claims.

### REFERENCES AND NOTES

1. Z. Xiao et al., Efficient perovskite light-emitting diodes featuring nanometre-sized crystallites. Nature Photonics, (2017).
2. L. N. Quan et al., Ligand-stabilized reduced-dimensionality perovskites. Journal of the American Chemical Society 138, 2649-2655 (2016).
3. H. Tsai et al., High-efficiency two-dimensional Ruddlesden-Popper perovskite solar cells. Nature 536, 312-316 (2016).
4. Z.-K. Tan et al., Bright light-emitting diodes based on organometal halide perovskite. Nature nanotechnology 9, 687-692 (2014).
5. B. E. Cohen, M. Wierzbowska, L. Etgar, High Efficiency and High Open Circuit Voltage in Quasi 2D Perovskite Based Solar Cells. Advanced Functional Materials, (2016).
6. Y. Liao et al., Highly-oriented low-dimensional tin halide perovskites with enhanced stability and photovoltaic performance. Journal of the American Chemical Society, (2017).
7. I. C. Smith, E. T. Hoke, D. Solis-Ibarra, M. D. McGehee, H. I. Karunadasa, A layered hybrid perovskite solar-cell absorber with enhanced moisture stability. Angewandte Chemie International Edition 53, 11232-11235 (2014).
8. D. H. Cao, C. C. Stoumpos, O. K. Farha, J. T. Hupp, M. G. Kanatzidis, 2D Homologous Perovskites as Light-Absorbing Materials for Solar Cell Applications. Journal of the American Chemical Society 137, 7843-7850 (2015).
9. L. N. Quan et al., Tailoring the Energy Landscape in Quasi-2D Halide Perovskites Enables Efficient Green-Light Emission. Nano Letters, (2017).
10. L. Pedesseau et al., Advances and Promises of Layered Halide Hybrid Perovskite Semiconductors. ACS nano 10, 9776-9786 (2016).
11. M. Yuan et al., Perovskite energy funnels for efficient light-emitting diodes. Nature Nanotechnology, (2016).
12. N. Wang et al., Perovskite light-emitting diodes based on solution-processed self-organized multiple quantum wells. Nature Photonics, (2016).
13. J.-C. Blancon et al., Extremely efficient internal exciton dissociation through edge states in layered 2D perovskites. Science, eaal4211 (2017).
14. O. Voznyy et al., A charge-orbital balance picture of doping in colloidal quantum dot solids. ACS nano 6, 8448-8455 (2012).
15. M. Pashley, Electron counting model and its application to island structures on molecular-beam epitaxy grown GaAs (001) and ZnSe (001). Physical Review B 40, 10481 (1989).
16. M. Lorenzon et al., Role of Nonradiative Defects and Environmental Oxygen on Exciton Recombination Processes in CsPbBr3 Perovskite Nanocrystals. Nano Letters, (2017).
17. Y. Zhang et al., Molecular oxygen induced in-gap states in PbS quantum dots. ACS nano 9, 10445-10452 (2015).
18. S. Takahashi, M. R. Badger, Photoprotection in plants: a new light on photosystem II damage. Trends in plant science 16, 53-60 (2011).
19. W. S. Yang et al., High-performance photovoltaic perovskite layers fabricated through intramolecular exchange. Science 348, 1234-1237 (2015).
20. N. Ahn et al., Highly reproducible perovskite solar cells with average efficiency of 18.3% and best efficiency of 19.7% fabricated via Lewis base adduct of lead (II) iodide. Journal of the American Chemical Society 137, 8696-8699 (2015).
21. J.-W. Lee, H.-S. Kim, N.-G. Park, Lewis acid-base adduct approach for high efficiency perovskite solar cells. Accounts of chemical research 49, 311-319 (2016).
22. A. Wakamiya et al., Reproducible fabrication of efficient perovskite-based solar cells: X-ray crystallographic studies on the formation of CH3NH3PbI3 layers. Chemistry Letters 43, 711-713 (2014).
23. G. Deacon, J. Green, Vibrational spectra of ligands and complexes-II Infra-red spectra (3650-375 cm−1 of triphenyl-phosphine, triphenylphosphine oxide, and their complexes. Spectrochimica Acta Part A: Molecular Spectroscopy 24, 845-852 (1968).
24. L. R. Becerra, C. B. Murray, R. G. Griffin, M. G. Bawendi, Investigation of the surface morphology of capped CdSe nanocrystallites by 31 P nuclear magnetic resonance. The Journal of chemical physics 100, 3297-3300 (1994).
25. H. Cho et al., Overcoming the electroluminescence efficiency limitations of perovskite light-emitting diodes. Science 350, 1222-1225 (2015).
26. N. J. Jeon et al., Compositional engineering of perovskite materials for high-performance solar cells. Nature 517, 476-480 (2015).
27. L. Zhao et al., In Situ Preparation of Metal Halide Perovskite Nanocrystal Thin Films for Improved Light-Emitting Devices. ACS nano, (2017).
28. N. Aristidou et al., The role of oxygen in the degradation of methylammonium lead trihalide perovskite photoactive layers. Angewandte Chemie International Edition 54, 8208-8212 (2015).
29. L. Zhao et al., Redox Chemistry Dominates the Degradation and Decomposition of Metal Halide Perovskite Optoelectronic Devices. ACS Energy Letters 1, 595-602 (2016).

1. A photovoltaic device, comprising:
a first electrode and a second electrode in a spaced-apart configuration;
an electron-transport layer coating at least a portion of the first electrode;
a light-harvesting layer coating at least a portion of the electron-transport layer and being in electrical communication with the first electrode and the second electrode, the light-harvesting layer comprising:
a quasi two-dimensional layered perovskite material in electrical communication with the first electrode and the second electrode; and
a passivating agent chemically bonded to the quasi two-dimensional layered perovskite material, the passivating agent comprising a phosphine oxide compound; and
a hole-transport layer coating at least a portion of the light-harvesting layer.

2. The photovoltaic device of claim 1, wherein:
the quasi two-dimensional layered perovskite material has at least one outermost edge comprising dangling bonds; and
the phosphine oxide compound of the passivating agent is chemically bonded to the dangling bonds.

3. The photovoltaic device of claim 1 or 2, wherein the quasi two-dimensional layered perovskite material is made of a metal-halide perovskite.

4. The photovoltaic device of claim 3, wherein the metal-halide perovskite is selected from the PEA₂Cs₍ₙ₋₁₋ₓ₎MAₓPbₙBr₃ₙ₊₁ family, x being smaller than n−1.

5. The photovoltaic device of claim 3, wherein the metal-halide perovskite is selected from the PEA₂K₍ₙ₋₁₋ₓ₎MAₓPbₙBr₃ₙ₊₁ family, x being smaller than n−1.

6. The photovoltaic device of claim 3, wherein the metal-halide perovskite is selected from the PEA₂Cs₍ₙ₋₁₋ₓ₎FAₓPbₙBr₃ₙ₊₁ family, x being smaller than n−1.

7. The photovoltaic device of any one of claims 1 to 6, wherein the quasi two-dimensional layered perovskite material comprises domains, each domain comprising between one and five monolayers.

8. The photovoltaic device of claim 7, wherein each monolayer comprises between two to four PbBr₆ unit cells.

9. The photovoltaic device of any one of claims 1 to 8, wherein the phosphine oxide compound is soluble in polar perovskite solvents and in non-polar antisolvents.

10. The photovoltaic device of claim 9, wherein the phosphine oxide compound is triphenylphosphine oxide (TPPO).

11. The photovoltaic device of any one of claims 1 to 10, wherein the first electrode is a conductive substrate.

12. The photovoltaic device of claim 11, wherein the conductive substrate is transparent.

13. The photovoltaic device of claim 11 or 12, wherein the conductive substrate comprises glass coated with indium tin oxide (ITO).

14. The photovoltaic device of any one of claims 1 to 13, wherein the second electrode comprises a layered stack of lithium fluoride (LiF) and aluminum (Al).

15. The photovoltaic device of any one of claims 1 to 14, wherein the hole-transport layer is made of PEDOT:PSS:PFI.

16. The photovoltaic device of any one of claims 1 to 15, wherein the electron-transport layer is made of TPBi.

17. A solar cell, comprising:
a light-harvesting layer, comprising:
a quasi two-dimensional layered perovskite material; and
a passivating agent chemically bonded to the quasi two-dimensional layered perovskite material, the passivating agent comprising a phosphine oxide compound.

18. The solar cell of claim 17, further comprising:
a first electrode;
an electron-transport layer coating at least a portion of the first electrode;
a hole-transport layer coating at least a portion of the light-harvesting layer; and
a second electrode coating at least a portion of the hole-transport layer, the second electrode being in electrical communication with the first electrode.

19. The solar cell of claim 17, further comprising:
a first electrode;
a hole-transport layer coating at least a portion of the first electrode;
an electron-transport layer coating at least a portion of the light-harvesting layer; and
a second electrode coating at least a portion of the electron-transport layer, the second electrode being in electrical communication with the first electrode.

20. The solar cell of claim 17, wherein the light-harvesting layer further comprises a mesoporous metal oxide material.

21. The solar cell of claim 20, the further comprising:
a first electrode;
a compact layer coating at least a portion of the first electrode;
a hole-transport layer coating at least a portion of the light-harvesting layer; and
a second electrode coating at least a portion of the hole-transport layer, the second electrode being in electrical communication with the first electrode.

22. The solar cell of claim 20, further comprising:
a first electrode;
a compact layer coating at least a portion of the first electrode;
an electron-transport layer coating at least a portion of the light-harvesting layer; and
a second electrode coating at least a portion of the electron-transport layer, the second electrode being in electrical communication with the first electrode.

23. The solar cell of any one of claims 17 to 23, further comprising a lower-bandgap subcell.

24. An optoelectronic device, comprising:
a first electrode and a second electrode in a spaced-apart configuration;
a quasi two-dimensional layered perovskite material in electrical communication with the first electrode and the second electrode; and
a passivating agent chemically bonded to the quasi two-dimensional layered perovskite material, the passivating agent comprising a phosphine oxide compound.

25. The optoelectronic device of claim 24, wherein:
the quasi two-dimensional layered perovskite material has at least one outermost edge comprising dangling bonds; and
the phosphine oxide compound of the passivating agent is chemically bonded to the dangling bonds.

26. The optoelectronic device of claim 24 or 25, wherein the quasi two-dimensional layered perovskite material is made of a metal-halide perovskite.

27. The optoelectronic device of claim 26, wherein the metal-halide perovskite is selected from the PEA₂Cs₍ₙ₋₁₋ₓ₎MAₓPbₙBr₃ₙ₊₁ family, x being smaller than n−1.

28. The optoelectronic device of claim 26, wherein the metal-halide perovskite is selected from the PEA₂K₍ₙ₋₁₋ₓ₎MAₓPbₙBr₃ₙ₊₁ family, x being smaller than n−1.

29. The optoelectronic device of claim 26, wherein the metal-halide perovskite is selected from the PEA₂Cs₍ₙ₋₁₋ₓ₎FAₓPbₙBr₃ₙ₊₁ family, x being smaller than n−1.

30. The optoelectronic device of any one of claims 24 to 29, wherein the quasi two-dimensional layered perovskite material comprises domains, each domain comprising between one and five monolayers.

31. The optoelectronic device of claim 30, wherein each monolayer comprises between two to four PbBr₆ unit cells.

32. The optoelectronic device of any one of claims 24 to 31, wherein the phosphine oxide is soluble in polar perovskite solvents and in non-polar antisolvents.

33. The optoelectronic device of claim 32, wherein the phosphine oxide is triphenylphosphine oxide (TPPO).

34. The optoelectronic device of any one of claims 24 to 33, wherein the first electrode is a conductive substrate.

35. The optoelectronic device of claim 34, wherein the conductive substrate is transparent.

36. The optoelectronic device of claim 34 or 35, wherein the conductive substrate comprises glass coated with indium tin oxide (ITO).

37. The optoelectronic device of any one of claims 24 to 36, wherein the second electrode comprises a layered stack of lithium fluoride (LiF) and aluminum (Al).

38. The optoelectronic device of any one of claims 24 to 37, further comprising a hole-injection layer sandwiched between the first electrode and the quasi two-dimensional layered perovskite material.

39. The optoelectronic device of claim 38, wherein the hole-injection layer is coating at least a portion of the first electrode.

40. The optoelectronic device of claim 38 or 39, wherein the hole-injection layer is made of PEDOT:PSS:PFI.

41. The optoelectronic device of any one of claims 24 to 40, further comprising an electron-transport layer sandwiched between the second electrode and the quasi two-dimensional layered perovskite material.

42. The optoelectronic device of claim 41, wherein the electron-transport layer is made of TPBi.

43. The optoelectronic device of claim 42 or 43, wherein the second electrode is coating at least a portion of the electron-transport layer.

44. A light-emitting diode, comprising:
a first electrode and a second electrode in a spaced-apart configuration;
a hole-injection layer coating at least a portion of the first electrode;
a light-emitting layer coating at least a portion of the hole-injection layer and being in electrical communication with the first electrode and the second electrode, the light-emitting material comprising:
a quasi two-dimensional layered perovskite material; and
a passivating agent chemically bonded to the quasi two-dimensional layered perovskite material, the passivating agent comprising a phosphine oxide compound; and
an electron-transport layer coating at least a portion of the light-emitting layer.

45. The light-emitting diode of claim 44, wherein at least one the hole-injection layer, the light-emitting layer and the electron-transport layer is solution-processed.

46. The light-emitting diode of claim 44 or 45, wherein the hole-injection layer, the light-emitted material and the electron-transport layer are stacked between the first electrode and the second electrode.

47. The light-emitting diode of any one of claims 44 to 46, wherein the LED is operable to generate an illuminating light having a spectral waveband ranging from about 490 nm to about 560 nm.

48. The light-emitting diode of claim 47, wherein the spectral waveband is centered at about 520 nm.

49. The light-emitting diode of any one of claims 44 to 48, wherein:
the quasi two-dimensional layered perovskite material has at least one outermost edge comprising dangling bonds; and
the phosphine oxide compound of the passivating agent is chemically bonded to the dangling bonds.

50. The light-emitting diode of any one of claims 44 to 49, wherein the quasi two-dimensional layered perovskite material is made of a metal-halide perovskite.

51. The light-emitting diode of claim 50, wherein the metal-halide perovskite is selected from the PEA₂Cs₍ₙ₋₁₋ₓ₎MAₓPbₙBr₃ₙ₊₁ family, x being smaller than n−1.

52. The light-emitting diode of claim 50, wherein the metal-halide perovskite is selected from the PEA₂K₍ₙ₋₁₋ₓ₎MAₓPbₙBr₃ₙ₊₁ family, x being smaller than n−1.

53. The light-emitting diode of claim 50, wherein the metal-halide perovskite is selected from the PEA₂Cs₍ₙ₋₁₋ₓ₎FAₓPbₙBr₃ₙ₊₁ family, x being smaller than n−1.

54. The light-emitting diode of any one of claims 44 to 53, wherein the quasi two-dimensional layered perovskite material comprises domains, each domain comprising between one and five monolayers.

55. The light-emitting diode of claim 54, wherein each monolayer comprises between two to four PbBr₆ unit cells.

56. The light-emitting diode of any one of claims 44 to 55, wherein the phosphine oxide is soluble in polar perovskite solvents and in non-polar antisolvents.

57. The light-emitting diode of claim 56, wherein the phosphine oxide is triphenylphosphine oxide (TPPO).

58. The light-emitting diode of any one of claims 44 to 57, wherein the first electrode is a conductive substrate.

59. The light-emitting diode of claim 58, wherein the conductive substrate is transparent.

60. The light-emitting diode of claim 58 or 59, wherein the conductive substrate comprises glass coated with indium tin oxide (ITO).

61. The light-emitting diode of any one of claims 44 to 60, wherein the second electrode comprises a layered stack of lithium fluoride (LiF) and aluminum (Al).

62. The light-emitting diode of any one of claims 44 to 61, wherein the hole-transport layer is made of PEDOT:PSS:PFI.

63. The light-emitting diode of any one of claims 44 to 62, wherein the electron-transport layer is made of TPBi.

64. An active material, the active material comprising:
a quasi two-dimensional perovskite compound, the quasi two-dimensional perovskite compound having at least one outermost edge; and
a passivating agent chemically bonded to the at least one outermost edge, the passivating agent comprising a phosphine oxide compound.

65. The active material of claim 64, wherein the quasi two-dimensional perovskite compound comprises domains, each domain comprising between one and five monolayers.

66. The active material of claim 64 or 65, wherein the quasi two-dimensional perovskite compound comprises a compound of general formula PEA₂Cs₍ₙ₋₁₋ₓ₎MAₓPbₙBr₃ₙ₊₁ family, x being smaller than n−1, wherein n is an integer greater than 0.

67. The active material of any one of claims 64 to 66, wherein a Cs-to-MA ratio ranges from 0% to 100%.

68. The active material of any one of claims 64 to 67, wherein the quasi two-dimensional perovskite compound is PEA₂Cs_{2.4}MA_{0.6}Pb₄Br₁₃.

69. A method for preparing a layer of active material, comprising:
dissolving precursors in a first solvent to obtain a perovskite precursor solution;
spin-coating the perovskite precursor solution on a surface to form a perovskite film on the surface;
spin-coating a mixture comprising a phosphine oxide compound and a second solvent on the perovskite film to form an intermediate film;
thermally treating the intermediate film, thereby obtaining the layer of active material, the active material comprising:
a quasi two-dimensional layered perovskite compound; and
a passivating agent chemically bonded to the quasi two-dimensional layered perovskite compound, the passivating agent comprising the phosphine oxide compound.

70. The method of claim 69, wherein the precursors comprise a PbBr₂ compound, a CsBr compound, a MABr compound and a PEABr compound.

71. The method of claim 70, wherein the PbBr₂ compound has a PbBr₂ molarity of about 0.6 M.

72. The method of claim 70 or 71, wherein the CsBr compound has a CsBr molarity of about 0.36 M.

73. The method of any one of claims 70 to 72, wherein the MABr compound has a MABr molarity of about 0.1 M.

74. The method of any one of claims 70 to 73, wherein the PEABr compound has a PEABr molarity of about 0.3 M.

75. The method of any one of claims 69 to 74, wherein the first solvent is dimethyl sulfoxide (DMSO).

76. The method of any one of claims 69 to 75, wherein the phosphine oxide compound is triphenylphosphine oxide (TPPO).

77. The method of any one of claims 69 to 76, wherein the second solvent is chloroform.

78. The method of any one of claims 69 to 77, wherein thermally treating the intermediate film is carried out at about 90° C. for about seven minutes.

79. A method for manufacturing a photovoltaic device, comprising:
electrically contacting a light-harvesting layer with a first electrode, the light-harvesting layer comprising:
a quasi two-dimensional layered perovskite material in electrical communication with the first electrode; and
a passivating agent chemically bonded to the quasi two-dimensional layered perovskite material, the passivating agent comprising the phosphine oxide compound;
electrically contacting the light-harvesting layer with a second electrode.

80. The method of claim 79, further comprising
preparing the light-harvesting layer, comprising:
dissolving precursors in a first solvent to obtain a perovskite precursor solution;
spin-coating the perovskite precursor solution on a surface to form a perovskite film on the surface;
spin-coating a mixture comprising a phosphine oxide compound and a second solvent on the perovskite film to form an intermediate film;
thermally treating the intermediate film, thereby obtaining the light-harvesting layer.

81. The method of claim 79 or 80, wherein the precursors comprise a PbBr₂ compound, a CsBr compound, a MABr compound and a PEABr compound.

82. The method of claim 81, wherein the PbBr₂ compound has a PbBr₂ molarity of about 0.6 M.

83. The method of claim 81 or 82, wherein the CsBr compound has a CsBr molarity of about 0.36 M.

84. The method of any one of claims 81 to 83, wherein the MABr compound has a MABr molarity of about 0.1 M.

85. The method of any one of claims 81 to 84, wherein the PEABr compound has a PEABr molarity of about 0.3 M.

86. The method of any one of claims 80 to 85, wherein the first solvent is dimethyl sulfoxide (DMSO).

87. The method of any one of claims 80 to 86, wherein the phosphine oxide compound is triphenylphosphine oxide (TPPO).

88. The method of any one of claims 80 to 87, wherein the second solvent is chloroform.

89. The method of any one of claims 80 to 88, wherein thermally treating the intermediate film is carried out at about 90° C. for about seven minutes.

90. The method of any one of claims 79 to 89, further comprising providing an electron-transport layer between the first electrode and the light-harvesting layer.

91. The method of claim 90, further comprising providing a hole-transport layer between the light-harvesting layer and the second electrode.

92. The method of any one of claims 79 to 89, further comprising providing a hole-transport layer between the first electrode and the light-harvesting layer.

93. The method of claim 92, further comprising providing an electron-transport layer between the light-harvesting layer and the second electrode.

94. A method for manufacturing an optoelectronic device, comprising:
coating a first electrode with a quasi two-dimensional layered perovskite material passivated with a passivating agent, the passivating agent being chemically bonded to the quasi two-dimensional layered perovskite material and comprising a phosphine oxide compound; and
electrically contacting the quasi two-dimensional layered perovskite material passivated with the passivating agent with a second electrode.

95. A method for manufacturing a light-emitting diode (LED), comprising:
electrically contacting a light-emitting layer with a first electrode, the light-emitting layer comprising:
a quasi two-dimensional layered perovskite material in electrical communication with the first electrode; and
a passivating agent chemically bonded to the quasi two-dimensional layered perovskite material, the passivating agent comprising the phosphine oxide compound;
electrically contacting the light-emitting layer with a second electrode.

96. The method of claim 95, further comprising:
preparing the light-emitting layer, comprising:
dissolving precursors in a first solvent to obtain a perovskite precursor solution;
spin-coating the perovskite precursor solution on a surface to form a perovskite film on the surface;
spin-coating a mixture comprising a phosphine oxide compound and a second solvent on the perovskite film to form an intermediate film;
thermally treating the intermediate film, thereby obtaining the light-emitting layer.

97. The method of claim 96, wherein the precursors comprise a PbBr₂ compound, a CsBr compound, a MABr compound and a PEABr compound.

98. The method of claim 97, wherein the PbBr₂ compound has a PbBr₂ molarity of about 0.6 M.

99. The method of claim 97 or 98, wherein the CsBr compound has a CsBr molarity of about 0.36 M.

100. The method of any one of claims 97 to 99, wherein the MABr compound has a MABr molarity of about 0.1 M.

101. The method of any one of claims 97 to 100, wherein the PEABr compound has a PEABr molarity of about 0.3 M.

102. The method of any one of claims 96 to 101, wherein the first solvent is dimethyl sulfoxide (DMSO).

103. The method of any one of claims 96 to 102, wherein the phosphine oxide compound is triphenylphosphine oxide (TPPO).

104. The method of any one of claims 96 to 103, wherein the second solvent is chloroform.

105. The method of any one of claims 96 to 104, wherein thermally treating the intermediate film is carried out at about 90° C. for about seven minutes.

106. The method of any one of claims 95 to 105, further comprising providing an electron-transport layer between the first electrode and the light-harvesting layer.

107. The method of claim 106, further comprising providing a hole-transport layer between the light-harvesting layer and the second electrode.

108. The method of any one of claims 95 to 105, further comprising providing a hole-transport layer between the first electrode and the light-harvesting layer.

109. The method of claim 108, further comprising providing an electron-transport layer between the light-harvesting layer and the second electrode.
